(19) United States
(12) Patent Application Publication
(10) Pub. No.: US 2025/0258349 A1
(43) Pub. Date: Aug. 14, 2025

(54) Apparatus and method for managing temperature of a high-power pluggable optical module

(71) Applicant: Ciena Corporation, Hanover, MD (US)

(72) Inventors: Rampratap Mahawar, Gurugram (IN); Chander Gupta, Gurugram (IN); Shubham Kumar, Gurugram (IN); Sachin Singla, Gurugram (IN); Bonnie Lynne Mack, Carp (CA)

(73) Assignee: Ciena Corporation, Hanover, MD (US)

(21) Appl. No.: 18/613,262

(22) Filed: Mar. 22, 2024

(30) Foreign Application Priority Data
Feb. 8, 2024 (IN) 202411008494

(51) Int. Cl. G02B 6/42; G02B 6/35

(52) U.S. Cl. CPC G02B 6/4269; G02B 6/3576; G02B 6/428; G02B 6/4284

(57) ABSTRACT

Systems and methods are provided for managing heat in network elements. A heat management apparatus, according to one implementation, includes a socket having an insertion opening configured to allow a pluggable optical module to be at least partially inserted within an interior of the socket. The heat management apparatus further includes a heat sink assembly configured to dissipate heat generated by the heat-generating element. Also, the heat management apparatus includes a positioning mechanism configured to move the heat sink assembly to a first position with respect to the socket while the pluggable optical module is being inserted into or removed from the insertion opening and further configured to move the heat sink assembly to a second position with respect to the socket after the pluggable optical module has been arranged within the interior of the socket.

### TECHNICAL FIELD

The present disclosure generally relates to temperature control systems for managing the temperature of electro-optic components in a network. More particularly, the present disclosure relates to an apparatus and method for dissipating heat associated with a high-power pluggable optical module in a high temperature environment and preserving heat in a low temperature environment.

### BACKGROUND

In networking equipment, such as routers, switches, cross-connects, Wavelength Division Multiplexing (WDM) terminals, and the like, pluggable optical transceivers are used for optical port connectivity. Example pluggable optical transceivers include modules such as XFP, XPAK, XENPAK, X2, XFP-E, SFP, SFP+, 300-pin, CFP, CFP2, CFP4, QSFP, QSFP28, QSFP-DD, OSFP, etc. Networking equipment including the pluggable optical modules is typically rated to operate in extended temperature ranges such as −40° C. to +85° C. Emerging small form factor packages for 100 Gb/s and higher optical modules, such as CFP4 (C Small Form Factor Pluggable 4), QSFP (Quad Small Form Factor Pluggable), and the like, are available in more limited temperature ranges such as 0° C. to +70° C. To assist with operation at higher temperatures, heat sinks may be used with a pluggable optical module. However, since the pluggable optical module is selectively inserted and removed through a slot in a device, conventional heat sinks rely on metal-to-metal contact between the pluggable optical module and a slot in the device. Of course, metal-to-metal contact does not provide a uniform or efficient thermal transfer between devices. It would be advantageous to include a Thermal Interface Material (TIM) between the heat sink and the pluggable optical module, but this material would “get in the way” during insertion and removal of the pluggable optical transceiver (note, as described herein the terms transceiver and module may be used interchangeably).

### BRIEF SUMMARY

The present disclosure is directed to heat sinks and heat management systems for controlling heat that is inherently generated by an electronic, electromechanical, and/or electro-optic devices, such as pluggable optical modules, during operation. A heat management apparatus in network equipment for a pluggable optical module includes a socket having an insertion opening configured to allow a pluggable optical module to be at least partially inserted within an interior of the socket; a heat sink assembly configured to dissipate heat generated by the heat-generating element; and a positioning mechanism including active circuitry configured to move the heat sink assembly to a first position with respect to the socket while the pluggable optical module is being inserted into or removed from the insertion opening and further configured to move the heat sink assembly to a second position with respect to the socket after the pluggable optical module has been arranged within the interior of the socket.

### BRIEF DESCRIPTION OF THE DRAWINGS

The present disclosure is illustrated and described herein with reference to the various drawings. Like reference numbers are used to denote like components/steps, as appropriate. Unless otherwise noted, components depicted in the drawings are not necessarily drawn to scale.

FIG. 1 is a photograph illustrating an issue with the wear and tear of a thermal pad incorporated on a heat sink when an optical module is repeatedly plugged in and unplugged from a socket.

FIG. 2 is a diagram illustrating different thermal resistances associated with the use of a heat sink for dissipating heat from an electro-optic component.

FIG. 3 is a table illustrating AT calculations for heat sinks with and without a thermal pad.

FIG. 4 is a bar graph illustrating AT versus power dissipation for heat sinks with and without a thermal pad.

FIG. 5 is a diagram illustrating an isometric view of a simulation model of a pluggable optical module.

FIG. 6A is a diagram illustrating an air gap caused by surface inconsistencies in a metal-to-metal interface between a heat-generating element and a heat sink device.

FIG. 6B is a diagram illustrating the use of a Thermal Interface Material (TIM) or thermal pad between the metal surfaces of a heat-generating element and a heat sink device for reducing or eliminating the air gap shown in FIG. 6A.

FIG. 7 is a thermal map illustrating a temperature profile of a heat sink without the use of a thermal pad.

FIG. 8 is a diagram illustrating a perspective view of a pluggable optical module plugged into a board-mounted socket with the use of a heat sink having a thermal pad.

FIG. 9 is a thermal map illustrating a temperature profile of the heat sink shown in FIG. 8 having a thermal pad.

FIG. 10 is a diagram illustrating an exploded perspective view of a heat management apparatus that includes a heat sink assembly and a positioning mechanism configured to position the heat sink assembly with respect to a socket that accommodates the pluggable optical module, according to various embodiments of the present disclosure.

FIG. 11A is a diagram illustrating a side view of the heat management apparatus of FIG. 10 with the heat management apparatus, for the pluggable optical module, arranged in a first position, according to various embodiments.

FIG. 11B is a diagram illustrating a zoomed-in side view of the heat management apparatus of FIG. 10 arranged in the first position as shown in FIG. 11A where protrusions are not positioned within corresponding grooves, according to various embodiments.

FIG. 12A is a diagram illustrating a perspective view of components at a bottom portion of the heat sink assembly shown in FIG. 10, according to various embodiments.

FIG. 12B is a diagram illustrating a zoomed-in perspective view of the metal strip, thread fiber net, and thermal pad shown in FIG. 12A in an assembled state, according to various embodiments.

FIG. 13 is a diagram illustrating the connector pinout of the socket shown in FIG. 10, according to various embodiments.

FIG. 14A is a photograph illustrating a side view of the heat management apparatus of FIG. 10 with a pluggable optical module plugged in, according to various embodiments.

FIG. 14B is a photograph illustrating a zoomed-in perspective view of a mechanical element used for detecting when the pluggable optical module is plugged into the socket, according to various embodiments.

FIG. 15 is a diagram illustrating a perspective view of a mechanical element on the socket for detecting when the pluggable optical module is plugged in, according to various embodiments.

FIG. 16A is a diagram illustrating a side view of the heat management apparatus of FIG. 10 with the heat management apparatus arranged in a second position, according to various embodiments.

FIG. 16B is a diagram illustrating a zoomed-in side view of the heat management apparatus of FIG. 10 arranged in the second position shown in FIG. 16A where protrusions are positioned within corresponding grooves, according to various embodiments.

FIG. 17 is a diagram illustrating the arrangement of the motor shown in FIG. 10 with respect to the socket, according to various embodiments.

FIG. 18 is a diagram illustrating an electro-mechanical switch attached to the socket for detecting the position of the heat sink assembly with respect to the socket, according to various embodiments.

FIG. 19 is a schematic diagram illustrating a dying gasp control device, according to various embodiments.

FIG. 20 is a state diagram illustrating actions and states of the heat management apparatus of FIG. 10, according to various embodiments.

FIG. 21 is a block diagram illustrating a process 270 for managing heat in an electronic, electromechanical, or electro-optical component, such as the pluggable optical module, according to various embodiments.

### DETAILED DESCRIPTION

Again, temperature management of electro-optical network components usually includes dissipating heat from high-power components such as pluggable optical modules. This becomes a greater challenge with the use of certain network components having a limited range of operating temperatures, as mentioned above. Not only is it important to reduce heat in a high temperature environment, but also, particularly with these limited temperature ranges, to preserve heat (i.e., reduce heat dissipation) in a low temperature environment.

Currently, there are few, if any, known solutions for market-grade temperature management systems for maintaining the temperature of network components in the range from about 0° C. to about 70° C. A first solution includes the use of thermal pads to provide better conductivity between one metal surface and another. One surface of the thermal pad may be coated with an anti-friction coating and the other surface may be coated with a sticky substance. However, an issue with this solution is that there is a high probability that the thermal pad may experience a significant amount of wear and tear during normal use. Also, the cost to service or replace these thermal pads can be high. Also, without the possibility of these heat sinks self-heating, it is typically not feasible to operate these devices below the lower temperature threshold of about 0° C.

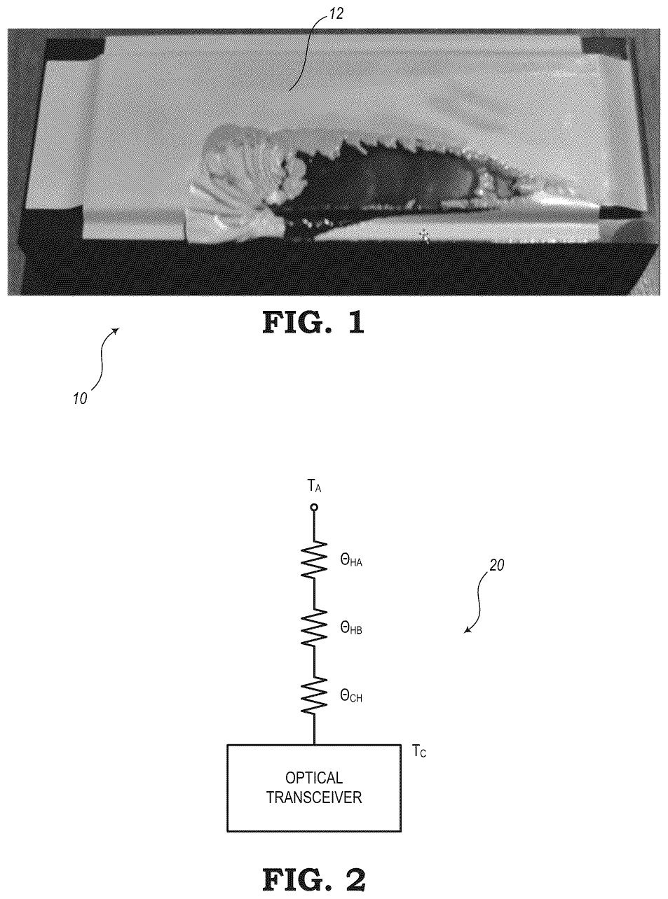

A second type of solution attempted in the field of heat sinks is to apply a polyamide layer on one surface of the thermal pad to hold a layer of phase change Thermal Interface Material (TIM). One problem with this attempt is that the thermal conductivity is too small (i.e., in the range of about 1.5 W/m-K). Also, self-heating of the network component is not possible for commercial optics in the extended temperature range below about 0° C. Also, as shown in FIG. 1, a heat sink 10 includes a TIM 12 that is not particularly robust and can easily tear, particularly when the electro-optical component (i.e., the pluggable optical module) is plugged and unplugged a number of times.

A third type of solution involves a mechanical lever that can be used to drop a heat sink down in contact with the component (pluggable optical module) that inherently generates heat and then raise the heat sink up when the component is being installed or removed. However, the reliability of this type of device is typically low and relies on a user to remember to manually raise or lower the heat sink at different times. Forgetting to do so can place the heat sink in a position where it is not in contact with the component that it is intended to dissipate heat from and therefore is unable to perform its heat dissipating function. On the other hand, forgetting to raise the heat sink can cause damage to the thermal pad or TIM 12, as shown in FIG. 1. Furthermore, self-heating of the electro-optical component is not possible for commercial optics in the extended low temperature range below 0° C. Also, this can cause the loss of heat sink fins to the drop-down mechanism.

Therefore, the embodiments of the present disclosure are configured to overcome the above-noted deficiencies of the conventional solutions. As such, the systems and methods described herein are configured to use high thermal conductive thermal pads to enhance heat dissipation, in pluggable optical modules, while also providing a mechanism that can automatically move the heat sink in the correct position based on whether or not the network component is already plugged into the socket. The systems and methods of the present disclosure are also configured to ensure that the heat sink does not have its thermal pad touching the heat-generating component when there is a chance that the component may be moved (i.e., being plugged into the socket or being removed from the socket). When it is determined that the component is stationary (i.e., already plugged into the socket), then the heat sink can be automatically lowered into position to provide heat dissipating functionality.

The systems and methods of the present disclosure are able to prevent or at least reduce the wear and tear on the thermal pads with the active transverse movement of the heat sink. Still, it has been found that using a thermal pad is beneficial in these types of heat sinks, particularly when certain pluggable optical modules are used that operate within the smaller temperature range from about 0° C. to about 70° C., since these thermal pads are able to provide better temperature control. Also, the present systems and methods do not require a large amount of space to accommodate a large manual lifting mechanism as used in conventional systems and therefore does not lose the space that could be used for heat sink fins for helping to dissipate heat.

### Optical Transceivers

Currently, telecom products support high-power optical transceivers in pluggable optical modules that can include Small Form-factor Pluggable (SFP) modules, such as Quad SFP-Double Density (QSFP-DD) modules, Octal SFP (OSFP) modules, C-Form-factor Pluggable (CFP), Digital Coherent Optics CFP (CFP2-DCO) modules, etc. These high-power optical transceivers may consume power of 20 W, 30 W, or more. With such high power, the process of cooling of these optical pluggables is not an easy task. Those skilled in the art will appreciate there are various different standards and specifications for pluggable optical modules, all of which are contemplated herewith. Specifically, the present disclosure addresses proper thermal management of such modules based on the fact they are physically inserted and removed, which adds physical complexity.

A conventional way of cooling these high-power devices includes fans and heat sinks (e.g., zipper-fin heat sinks), heat pipes, or vapor chamber-based heat sinks. To cool extra power emitted by the pluggable optical module, the size of heat sinks can be increased to dissipate a greater amount of heat into the surrounding air to essentially cool the pluggable optical module.

### Limitations of Prior Solutions

However, there are certain limitations associated with the conventional cooling systems. First, for instance, is that it can be difficult to cool a component, particularly in a confined space, when the temperature difference (ΔT) between an ambient temperature (Tₐ) and a transceiver case temperature (T_{c}) is less than 40° C. Thus, when Tₐ is already high, it can be difficult to cool the component's T_{c} to a level within a proper operating range. With the heat that is emitted from 20 W-30 W transceivers, a T_{c} of more than 85° C. may be reached when the Tₐ is 45° C. Therefore, the conventional systems can have difficulty running at a suitable temperature when Tₐ is, say, 65° C.

Also, after a size increment of the heat sink and running fans at a particular speed (in RPM), the AT saturates and T_{c} is unable to drop further, even with an increase in the size of heat sink or an increase in the fan speed.

### Thermal Resistances

FIG. 2 is a diagram illustrating different thermal resistances associated with the use of a heat sink for dissipating heat from an electro-optic component (e.g., pluggable module, optical transceiver, etc.), essentially resulting in the thermal resistance circuit 20 as shown. The thermal resistance circuit 20 includes three resistances—θCH, θHB, and θHA, which play a role in creating ΔT (i.e., T_{c} minus Tₐ) for cooling the pluggable optical module.

The term θHA is the heat sink-to-ambient air thermal resistance, which is formed between the fins of the heat sink and surrounding air. This term varies based on air speed flowing through the fins. Also, this term inherently saturates (e.g., it is limited to a maximum amount). That is, increasing the surface area of the fins of the heat sink and increasing the air speed beyond a certain point does not help to further reduce the T_{c}.

The term θHB is the heat sink body thermal resistance. This includes the resistance of metal, heat pipes, vapor chamber, etc. present in the heat sink body to distribute the heat inside the heat sink. This term is also fixed and may not be sufficient to cool the high-power pluggable optical module.

The term θCH is the contact thermal resistance between the case of the optical transceiver and bottom surface of the heat sink that contacts the optical transceiver. Currently, this is normally a metal-to-metal solid contact in all types of connectors (e.g., QSFP-DD, QSFP-DD800, CFP2-DCO etc.).

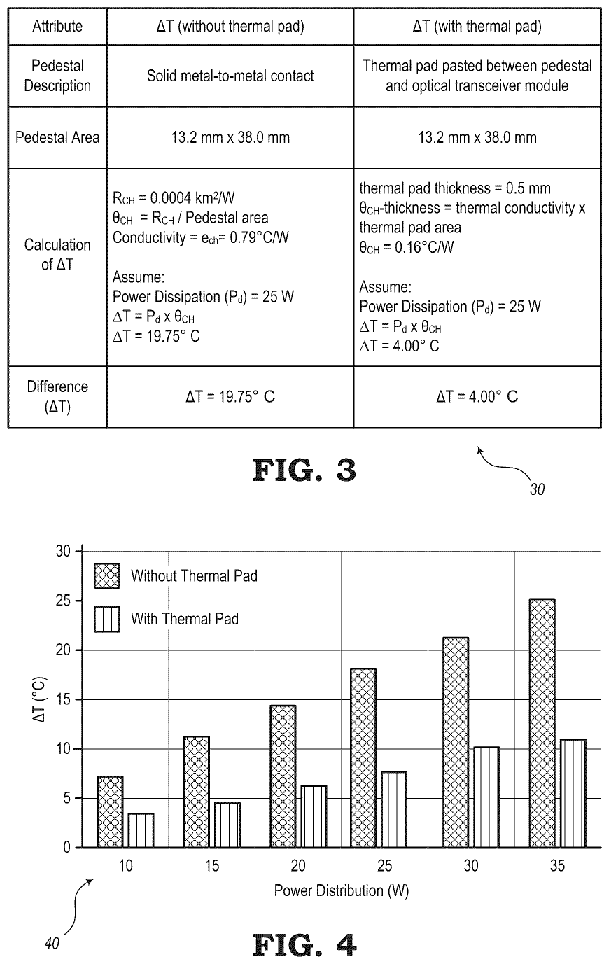

FIG. 3 is a table 30 illustrating an example of ΔT calculations for heat sinks with and without a thermal pad. Based on the calculations, the table 30 shows that there is a satisfactory decrease of case temperature (T_{c}) by almost 15° C. for a network component (e.g., pluggable optical module) operating at a power of 25 W when using a thermal pad instead of simply using a pressure dry contact (e.g., metal-to-metal contact, without a thermal pad, etc.).

FIG. 4 is a bar graph 40 illustrating ΔT versus power dissipation for heat sinks with and without a thermal pad. The bar graph 40 shows that network components (e.g., pluggable optical module) operating at a higher power (in Watts) will be able to experience an ever-increasing temperature decrease. For example, the bar graph 40 shows that a device operating at a power dissipation level of 35 W would experience a ΔT of 25.3° C. without a thermal pad and a ΔT of 10.8° C. with a thermal pad, which would be a satisfactory reduction of 14.5° C. This decrease in temperature will further improve with an increase in the power dissipation. In other words, it is possible to get a higher temperature benefit when power dissipation increases.

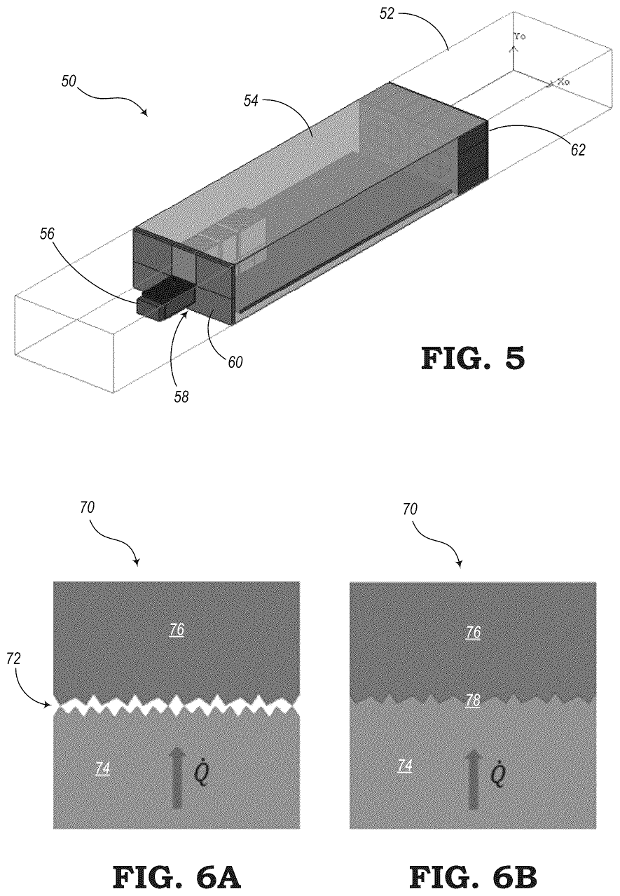

FIG. 5 is a diagram illustrating an isometric view of a simulation model 50 of a pluggable optical module. As shown, the simulation model 50 includes a system domain 52, an enclosure 54, an optical module 56 (e.g., optical transceiver, pluggable device, etc.) inserted into an insertion opening 58 in a faceplate 60 of the enclosure 54, and fans 62. For example, the fans 62 may be configured to generate about 6 cubic feet per minute (i.e., 6 cfm) through a vented back panel of the enclosure 54.

In this simulation model 50, the optical module 56 includes a dry contact with a thermal pad (as preferred in some embodiments). The condition of the boundary of the system domain 52 includes an ambient temperature Tₐ+65° C. The power dissipation of the optical module 56 is simulated at 25 W. A heat sink (not shown) used for heat dissipation is an aluminum zipper fin type. The contact resistance (θCH) is set to 0.0004 Km2/W and the Printed Circuit Board (PCB) conductivity is set to 0.3 W/mK in an axial direction and is set to 40 W/mK in the planar direction.

### Thermal Interface Material (TIM)

FIG. 6A is a diagram illustrating a metal-to-metal interface 70 (or dry contact) having an air gap 72 caused by surface inconsistencies in both a network component 74 (e.g., heat-generating element) and a heat sink 76 configured to dissipate heat from the network component 74. It may be noted that the surface irregularities may be exaggerated in these diagrams to emphasize the air gap 72 in order to demonstrate how the conductivity of heat may be interrupted without the use of a thermal pad. FIG. 6B is a diagram illustrating the use of a TIM 78 sandwiched between the network component 74 and the heat sink 76. It may be noted that the TIM 78 or thermal pad between the metal surfaces of a heat-generating element and a heat sink device can be used for reducing or eliminating the air gap 72 shown in FIG. 6A and reducing the thermal resistance, allowing for greater heat transfer.

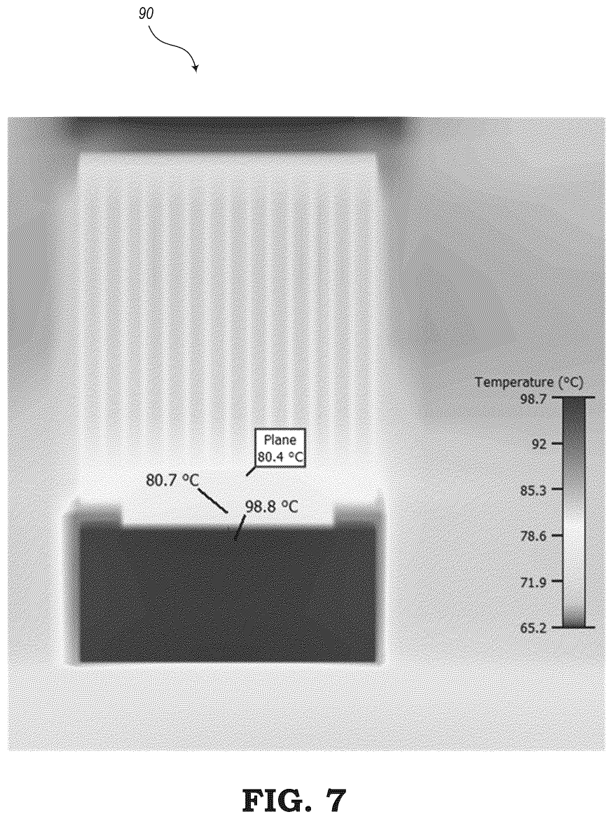

FIG. 7 is a thermal map 90 illustrating a temperature profile of a heat sink without the use of a thermal pad. In this example scenario, the case temperature (T_{c}) raised to an unacceptably high temperature of 98.5° C. The “case” refers to a housing of the pluggable optical module.

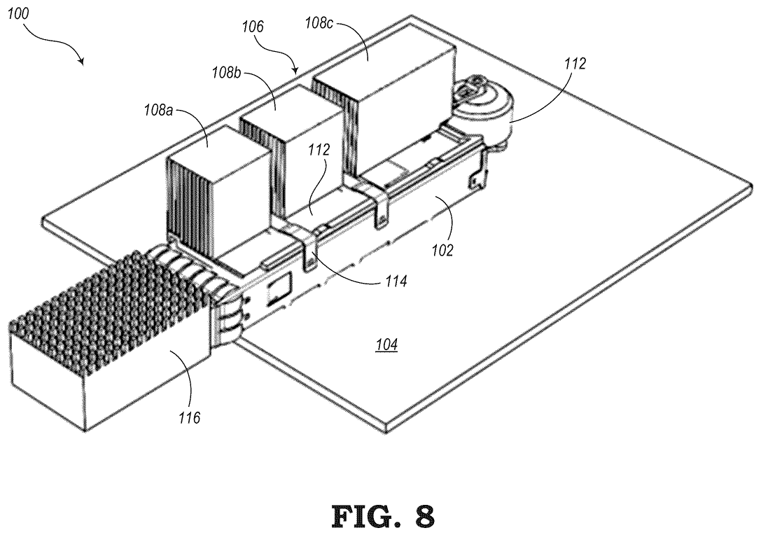

FIG. 8 is a diagram illustrating a perspective view of an embodiment of network equipment 100, according to various embodiments of the present disclosure. The network equipment 100 includes a socket 102 attached to a circuit board 104 or PCB. The network equipment 100 further includes a heat sink assembly 106 including at least a first group of fins 108a, a second group of fins 108b, and a third group of fins 108c. The heat sink assembly 106 can further include a thermal pad 110 (or TIM) between its base and the socket 102 (or pluggable optical module 116).

Furthermore, the network equipment 100 includes a motor 112 configured to automatically move the heat sink assembly 106 between an upper position and a lower position. In the upper position, the thermal pad 110 is lifted. This allows the pluggable optical module 116 to be inserted in (plugged into) the socket 102 and/or be removed (unplugged) from the socket 102 without causing damage to the thermal pad 110. Also, a clip 114 is used to confine the heat sink assembly 106 to the upper position, lower position, and positions therebetween.

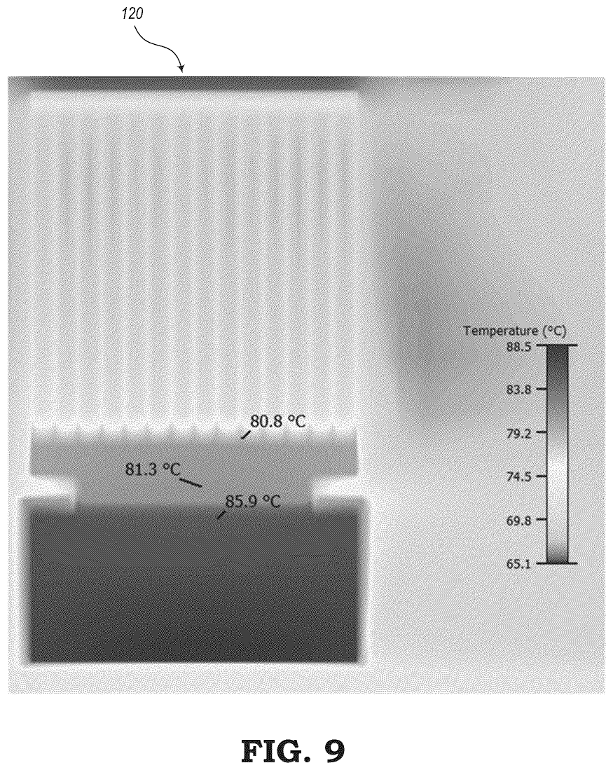

FIG. 9 is a thermal map 120 illustrating a temperature profile of the network equipment 100 of FIG. 8, which in the preferred embodiments includes the thermal pad 110, protected from damage by the positioning mechanism (e.g., including at least the motor 112). In this case, with the thermal pad 110, the case temperature (T_{c}) of the socket 102 (or pluggable optical module 116) in this scenario is 85.9° C., which is a decrease of 12.6° C. compared with the system without the thermal pad.

Thus, the simulations described with respect to FIGS. 5-9 result in a difference of 12-13° C., which is comparable to the difference calculated in the examples described with respect to FIGS. 2-4. Therefore, it can be concluded from the calculations and the simulations that a beneficial difference of about 12-15° C. can be realized using a thermal pad with high-power (e.g., 25 W) pluggable optical modules. In additional testing, it was discovered that thermal pads on pluggable optical modules with 15 W power provided a temperature reduction of about 7° C. when compared to systems with dry contact (or no thermal pad).

Thus, it can be concluded that it is possible to reduce case temperature of high-power pluggable optical modules drastically with solutions that include thermal pads. Again, the hurdle in the design concept is how to introduce a thermal pad into the cooling solution in a reliable manner to effectively reduce thermal resistance while also preventing excessive wear and tear on the thermal pad.

In some cases, others in the industry have attempted to decrease the heat sink to plug thermal resistance. For example, one approach includes a coating that is applied to a pedestal of the heat sink. However, testing has shown that it does not significantly decrease the thermal resistance with the forces that are applied by a cage spring clip. Another approach includes a phase change material protected by a thin polymer coating to be applied to the heat sink pedestal. This was found to be subject to tearing when a pluggable optical module was inserted in its cage.

Recently, a further approach includes a “drop-down heat sink,” which uses a custom cage and heat sink with a spring internal to the cage. The tape or coating above can also be applied to the base of the pedestal. An empty cage has the heat sink in a raised position, so a pluggable optical module does not come in contact with the heat sink pedestal during insertion. When the pluggable optical module is inserted in the cage, it contacts the spring mechanism at the back of the cage, which drops the heat sink down to contact the surface of the pluggable optical module. However, testing of this concept has shown that the loss in area available for the heat sink fins, due to the large size of the mechanism, is not compensated by the phase change TIM on the heat sink. Also, some tearing of the phase change TIM has also been noticed in reliability testing.

### Heat Management Apparatus

Therefore, to overcome the issues with the conventional systems, the following solutions are proposed. It should be noted that the embodiments of the present disclosure are configured to avoid wear and tear of the thermal pad during the actions of plugging the heat-generating pluggable optical module into the socket of the optical module and/or unplugging the electro-optical component from the socket. When the pluggable optical module is inserted in the socket, a positioning mechanism formed with the socket is configured to lift the thermal pad (attached to the heat sink) up and away from the component to avoid damage to the thermal pad during the sliding process. Then, when the pluggable optical module is properly plugged into the socket and in a stationary position, the positioning mechanism can then lower the heat sink (and thermal pad) down to the heated surface of the socket and/or pluggable optical module.

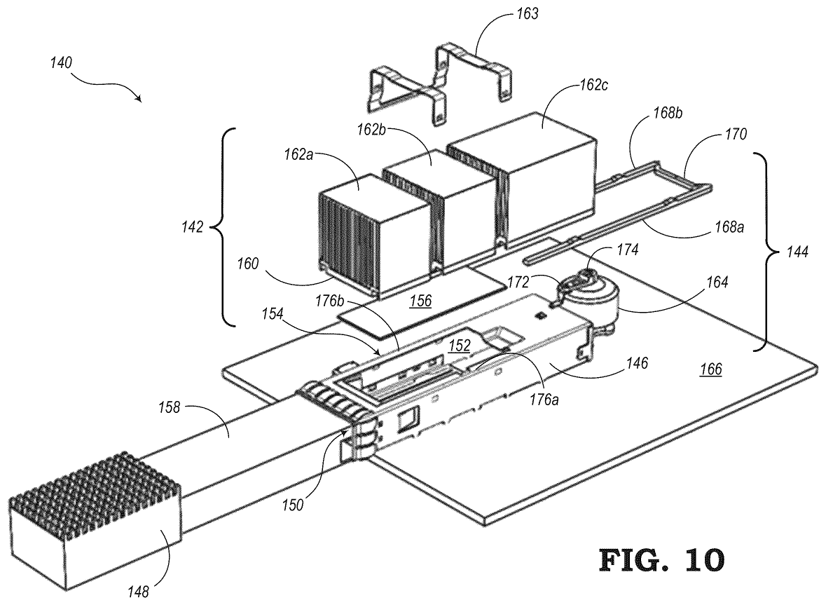

FIG. 10 is an exploded perspective view of an embodiment of a heat management apparatus 140 having many similarities to the embodiment of FIG. 8. As illustrated in FIG. 10, the heat management apparatus 140 includes a heat sink assembly 142 and a positioning mechanism 144 configured to position the heat sink assembly 142 with respect to a socket 146 (e.g., slot, receptable, cage, case, housing, etc.) that is configured to accommodate a pluggable optical module 148 or other type of pluggable component that inherently generates heat during operation and which is selectively inserted in network equipment. In some cases, the pluggable optical module 148 may be referred to as a heat-generating element even though the generation of heat is merely a byproduct of the normal operations of the component. The positioning mechanism 144 can include active circuitry that is configured to position the heat sink assembly 142 up or down as needed, automatically.

The socket 146 of the heat management apparatus 140 includes an insertion opening 150. As shown in FIG. 10, a back end of the pluggable optical module 148 is already partially inserted into the insertion opening 150. The insertion opening 150 and interior 152 of the socket 146 are configured to allow the pluggable optical module 148 (e.g., heat-generating element) to be at least partially inserted within the interior 152 of the socket 146. The heat sink assembly 142 is configured to dissipate heat generated by the pluggable optical module 148. The positioning mechanism 144 is configured to lift the heat sink assembly 142 to a first position (e.g., upper position) with respect to the socket 146 while the pluggable optical module (e.g., pluggable optical module 148) is being inserted into or removed from the insertion opening 150 and further configured to lower the heat sink assembly to a second position (e.g., lower position) with respect to the socket 146 after the pluggable optical module has been arranged within the interior 152 of the socket 146.

The socket 146 further includes a window 154 (e.g., in a top surface of the socket 146), wherein the positioning mechanism 144 is configured to move the heat sink assembly 142 out of and/or away from the window 154 to the first position while the pluggable optical module 148 is being inserted into or removed from the insertion opening 150, and wherein the positioning mechanism 144 is configured to move the heat sink assembly 142 towards and/or into the window 154 to the second position after the pluggable optical module 148 has been arranged within the interior 152 of the socket 146.

In the second (e.g., lower) position, the heat sink assembly 142 contacts the heat-generating element. In some embodiments, the heat sink assembly 142 includes a thermal pad 156 having a Thermal Interface Material (TIM). The thermal pad 156 is configured to contact a surface (e.g., top surface 158) of the pluggable optical module 148 (i.e., when fully inserted within the interior 152) when the positioning mechanism 144 has moved the heat sink assembly 142 to the second position. It should be noted that the action moving the heat sink assembly 142 to the first (e.g., upper) position while the pluggable optical module is in the process of being inserted into or being removed from the insertion opening 150 avoids wear and tear on the thermal pad 156, since the thermal pad 156 is attached to a bottom portion of the heat sink assembly 142 and is moved away from the contact surface (e.g., top surface 158) during the transverse movement of the pluggable optical module 148 during the plugging in and unplugging actions.

The heat sink assembly 142 further includes a base 160 and one or more groups of fins 162a, 162b, 162c extending (upward) from the base 160. A clip 163 is configured to support the heat sink assembly 142 with respect to the socket 146. The clip 163 includes horizontal arms that fit in gaps between the groups of fins 162a, 162b, 162c and may contact the base 160. It should be noted, however, the clip 163 does not hold the heat sink assembly 142 in a fixed position, but rather enables the positioning mechanism 144 to move heat sink assembly 142 with respect to the socket 146 in either an upward direction away from the socket 146 or downward direction towards the socket 146.

In some embodiments, a flexible material (e.g., rubber, foam, etc.) may be formed between a bottom portion of the horizontal arms of the clip 163 and a top surface of the base 160 to substantially support the heat sink assembly 142 while also allowing up and down movement thereof. This flexible material is configured to apply a suitable amount of pressure to hold the thermal pad 156 in contact with the pluggable optical module 148 to thereby reduce the thermal resistance (θCH) when the thermal pad 156 is lowered in contact with the heated surface of the pluggable optical module 148.

In addition, the positioning mechanism 144 of the heat management apparatus 140 includes a motor 164 (e.g., stepper motor). The socket 146 and motor 164 may be mounted, for example, on a substrate 166 (e.g., circuit board, PCB, etc.). The positioning mechanism 144 also includes a slider having a pair of reciprocating arms 168a, 168b connected to a shoulder 170. The motor 164 includes a radial arm 172 connected to a shaft 174. The radial arm 172 is pivotally attached to the shoulder 170.

Rotation of the shaft 174 causes the radial arm 172 to move the slider by moving the shoulder 170 in a forward or backward direction, thereby causing the reciprocating arms 168a, 168b to slide back and forth within channels in the base 160 of the heat sink assembly 142. Also, the reciprocating arms 168a, 168b may be configured to slide along edges 176a, 176b, respectively, on a top surface of the socket 146.

As mentioned in more detail below, the reciprocating arms 168a, 168b include protrusions that can be used to push the heat sink assembly 142 in an upward direction to the first (upper) position or allow the heat sink assembly 142 to be lowered in a downward direction to the second (lower) position. The positioning mechanism 144 may be based on a slider-crank mechanism to lift or lower the heat sink assembly 142.

### Upper (Lifted) Position

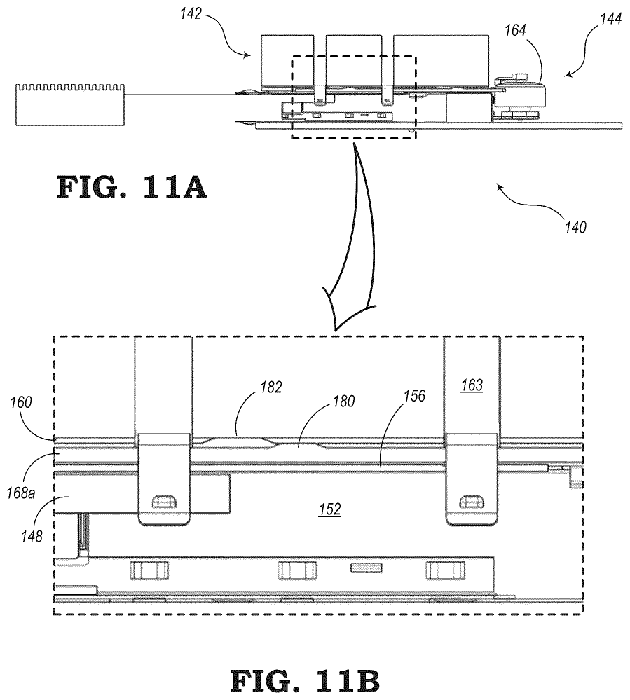

FIG. 11A is a diagram illustrating a side view of the heat management apparatus 140 with the heat sink assembly 142 arranged in the first (upper) position. FIG. 11B is a diagram illustrating a zoomed-in side view of the heat management apparatus 140. Each of the reciprocating arms 168a, 168b (where reciprocating arm 168a is shown in FIG. 11B) includes one or more protrusions 180. Also, the base 160 of the heat sink assembly 142 includes corresponding grooves 182. It should be noted that the protrusions 180 and grooves 182 may include any suitable size and shape.

As illustrated, when the heat sink assembly 142 is in the first (upper) position, the protrusions 180 are not positioned within the grooves 182. As mentioned above, the bottom of the reciprocating arms 168a, 168b are configured to slide along edges 176a, 176b (not shown in FIG. 11B), respectively, on the top of the socket 146. Since the protrusions 180 are not seated in the grooves 182 in this case, the protrusions 180 push along bottom edges of the base 160, thereby lifting the heat sink assembly 142. In the lifted position, the thermal pad 156 is raised above the path of the pluggable optical module 148 as it is inserted into or removed from the interior 152 of the socket 146. In some embodiments, the size of the protrusions 180 and grooves 182 may be increased to thereby increase the clearance between the thermal pad 156 and the pluggable optical module 148 during insertion.

The upper (or lifted) position, as shown in FIGS. 11A and 11B, may be considered to be a default position. Thus, when there is a possibility that the pluggable optical module 148 is being plugged in and/or unplugged and pulled out of the socket 146, the heat sink assembly 142, and hence the thermal pad 156 can be moved out of the way to avoid damage thereto.

Regarding the thermal pad 156, conventional systems faced certain challenges that are overcome by the embodiments of the present disclosure. For example, a first challenge is keeping the thermal pad 156 stuck to the heat sink and not stuck to the inserted pluggable optical module 148. A second challenge is with the thermal pad 156 drying out over time. And a third challenge is the wear and tear on the thermal pad 156 during the plugging in and unplugging actions (as suggested throughout the present disclosure). The following embodiments are configured to cater to the first two of these challenges.

### Heat Sink Assembly

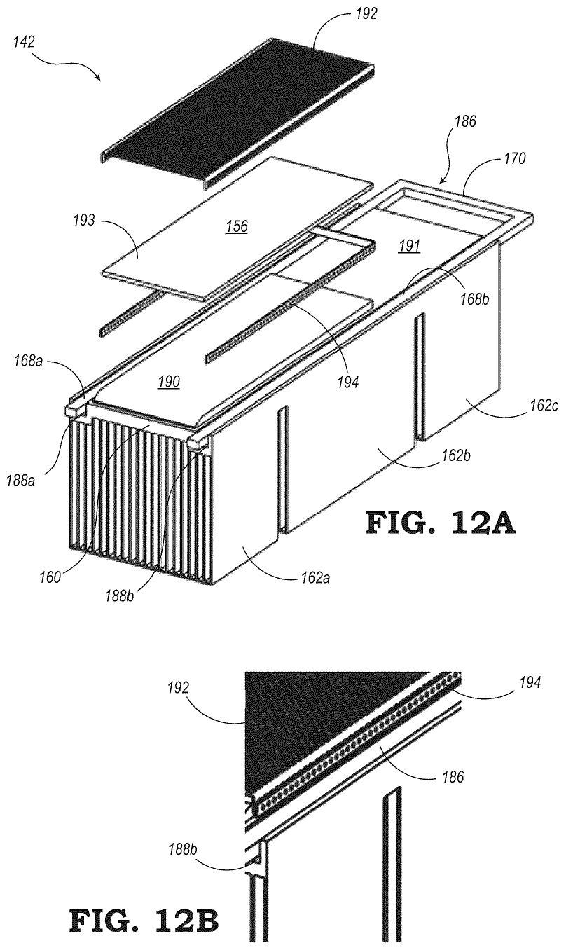

FIG. 12A is an exploded view of an embodiment of the components incorporated at a bottom portion of the heat sink assembly 142. As mentioned above, the heat sink assembly 142 includes the groups of fins 162a, 162b, 162c extending from the base 160. A slider 186, which includes the reciprocating arms 168a, 168b and shoulder 170, is part of the positioning mechanism 144 for moving the heat sink assembly 142. The base 160 includes channels 188a, 188b in which the reciprocating arms 168a, 168b are able to slide.

Furthermore, the heat sink assembly 142 may include a pedestal 190 formed between the bottom 191 of the base 160 and the thermal pad 156. A thin thread fiber net 192 may be wrapped around the bottom surface 193 of the thermal pad 156 and held in place using a metal strip 194. FIG. 12B is a diagram illustrating a zoomed-in perspective view of the metal strip 194, thread fiber net 192, and thermal pad 156 shown in FIG. 12A in an assembled state. The thread fiber net 192 may be mounted on the thermal pad 156 using a strong adhesive.

The thin thread fiber net 192 can be fitted to the thermal pad 156 and pedestal 190 from the sides with the metal strip 194 keeping the thread fiber net 192 squeezed properly. The metal strip 194 may be fitted with small screws from sides. The thread fiber net 192 is configured to cover the thermal pad 156 and restrict the thermal pad 156 from sticking with the pluggable optical module or other heat-generating components. Again, this can help to avoid wear and tear of the thermal pad 156. A benefit of the thread fiber net 192 is that it can contain an elastomeric-based material that can prevent the thermal pad 156 from drying up over a long time.

In some embodiments, the thread fiber net 192 may have gaps in between weaves such that thermal pad 156 can make good contact between the pedestal 190 and the surface of the heat-generating component (e.g., pluggable optical module 148), thereby providing good conductivity and reducing the thermal resistance (θCH). For example, thermal pads with fiber nets may include:
a) THERM-A-GAP (G974) from Parker Chomerics (having a fiberglass cover, high conductivity of 5 W/m-K including woven glass, and a thickness of 0.5 mm), b) CompaTherm from Nolato (having a CompaTherm Pad 9451 as a cost effective thermally conductive interface material, a filled thermally conductive elastomer which provides good thermal performance and reliability), where CompaTherm Pad 9451 has properties of 5 W/(mK) thermal conductivity, an operating temperature from −40° C. to +150° C., electrically insulating material, compliant elastomeric based material, naturally tacky on both sides, and thickness from 0.5 to 5 mm,
c) other similar thermal pads.

Returning again to FIG. 10, according to various embodiments, the positioning mechanism 144 may include the one or more reciprocating arms 168a, 168b, which are configured to slide within one or more corresponding channels 188a, 188b in the base 160 of the heat sink assembly 142. Each of the one or more reciprocating arms 168a, 168b may include one or more protrusions 180 corresponding to one or more grooves 182 in the respective channel 188a, 188b. The positioning mechanism 144 may further include a stepper motor (e.g., motor 164) configured to move the one or more reciprocating arms 168a, 168b in a reciprocating manner within the one or more corresponding channels 188a, 188b. The positioning mechanism 144 therefore can move the heat sink assembly 142 to the first (upper) position by sliding the one or more reciprocating arms 168a, 168b such that the protrusions 180 are not positioned within the grooves 182 and can move the heat sink assembly 142 to the second (lower) position by sliding the one or more reciprocating arms 168a, 168b such that the protrusions 180 are positioned (seated) within the grooves 182.

Generally, the heat management apparatus 140 may be configured to work with any type of heat-generating element (e.g., electrical component, electromechanical component, electro-optical component, the pluggable optical module, etc.). The socket 146 may be arranged on a circuit board (e.g., substrate 166). The heat management apparatus 140 may include any suitable type of support structure, such as the clip 163, which may be configured to support the heat sink assembly 142 while allowing the heat sink assembly 142 to move in a substantially linear manner between the first position and the second position.

### Use Case #1: Inserting (Plugging in) the Heat-Generating Component

In a default position, the heat sink assembly 142 is lifted up to the upper position. As such, the heat sink assembly 142 will not be in the down position when the socket 146 is empty, such as when a heat-generating component (e.g., the pluggable optical module 148) is absent (e.g., not inserted, not plugged in, etc.).

First, when the power to the socket 146 (and other elements mounted on the substrate 166) is off, the heat-generating component can be inserted, plugged in, unplugged, removed, or other such insertion, removal, or sliding movements. Since the heat sink assembly 142 is in a lifted-up position by default, while power is off, plugging in and pulling out the heat-generating component can be done freely without touching the sensitive elements of the heat sink. That is, the component will not scrape against the thermal pad during movement in or out of the socket interior and therefore will not damage the thermal pad.

When power is on and the heat-generating component is inserted in the socket while the heat sink assembly is in the lifted-up default position, the socket 146 may include connections for receiving corresponding plugs of the pluggable optical module 148. Also, the socket 146 may include sensors for detecting the presence of the plugs plugged into its connectors. When the heat-generating component (“module” or “MOD”) is absent (“ABS”), the sensors may set a “MOD_ABS” bit to one. However, when a module is plugged in, the MOD_ABS is reset to zero. Thus, when the module (e.g., pluggable optical module 148) is fully inserted and plugged in, the MOD_ABS goes low and then a controller will know that a module has been inserted.

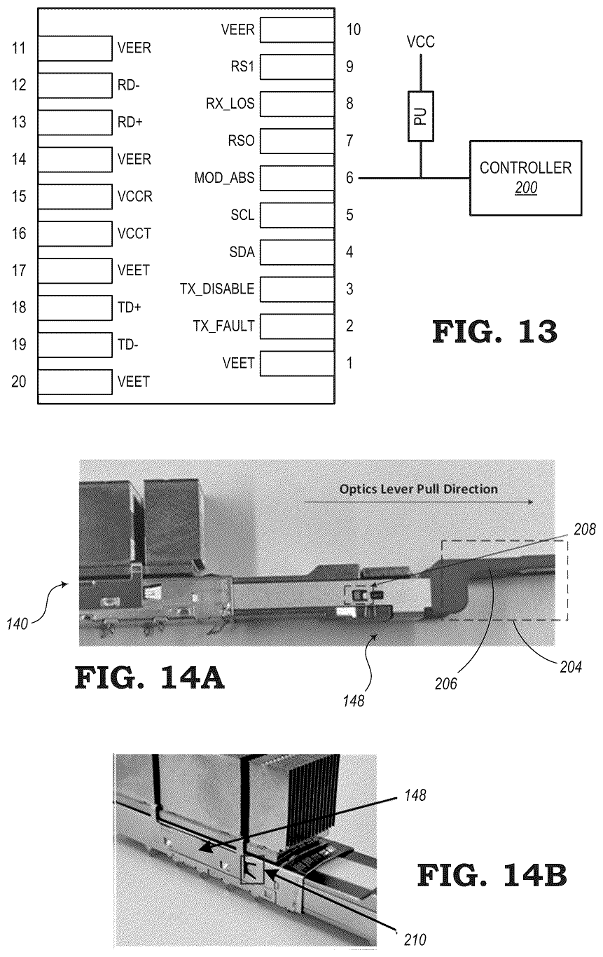

FIG. 13 is a diagram illustrating an embodiment of a connector pinout of the socket 146. As shown, pin 6 is configured to output the MOD_ABS bit, which can be supplied to a controller 200. When the MOD_ABS bit is high (i.e., module absent or not connected), the controller 200 is configured to provide a signal to the motor 164 to lift the heat sink assembly 142. When the module is inserted and plugged in and the MOD_ABS bit is low, the controller 200 is configured to provide a signal to the motor 164 to lower the heat sink assembly 142 for normal heat dissipating functionality. In some embodiments, circuitry connected to the controller 200 may include a debounce delay circuit for eliminating debounce during the transition from one phase to another.

### Use Case #2: Removing (Unplugging) the Heat-Generating Component

In some situations, the MOD_ABS signal might not be able to provide adequate warning that the module is in the process of being removed. That is, while the module is being removed, the MOD_ABS signal may remain low when the pluggable optical module is still connected before the module is fully removed from the socket or cage. For example, this movement distance may be the insertion length of the connectors and plugs.

To avoid damaging the thermal pad in this situation, certain techniques may be used. In one embodiment, the user may press a “release button” or other suitable mechanical switch, button, etc., whereby, upon pressing the button, a signal is sent to the controller 200 to cause the positioning mechanism 144 to lift the heat sink assembly to the safe upper position. Another embodiment is described below.

FIG. 14A is a photograph illustrating a side view of the heat management apparatus 140 with the pluggable optical module 148 plugged in, in accordance with another embodiment in which the pluggable optical module 148 is being removed while power is on. Also, FIG. 14B is a photograph illustrating a zoomed-in perspective view of a mechanical element used for detecting when the pluggable optical module 148 is plugged into the socket 146.

In these embodiments, the socket 146 may be configured to detect slight movements of the module in advance of the module making any significant movements that might damage the thermal pad. The pluggable optical module 148 may include a lever 204 (e.g., part of a handle 206 of the pluggable optical module 148). Before the module (e.g., pluggable optical module 148) is removed, a first latch 208 on the pluggable optical module 148 is moved in cooperation with the lever 204 before the module is disconnected from the connectors. Also, the first latch 208 may press a second latch 210 of the socket 146, where movement on the order of about 0.5 mm can be detected. In response, the controller 200 can cause the positioning mechanism 144 to lift the heat sink assembly 142.

The embodiments shown in FIGS. 14A and 14B may include the following procedure:
1. Lever 204 is held by an operator using any finger,
2. Lever 204 is then pulled by the operator,
3. By design, this makes first pull of the lever 204 for a short distance, without moving out of the actual pluggable optical module,
4. Using lever 204, the first latch 208 is pushed outwards,
5. The first latch 208 pushes the second latch 210 on the socket (e.g., QSFP-DD cage). The second latch 210 keeps the module plug locked with the socket, where a lock gets unlocked when second latch 210 is pushed outward,
6. Once the module plug is unlocked, it is free to come out of the cage. Before this lock is unlocked, the module plug does not make any movements,
7. After unlocking the plug, the operator can further pull the module out using the handle 206.

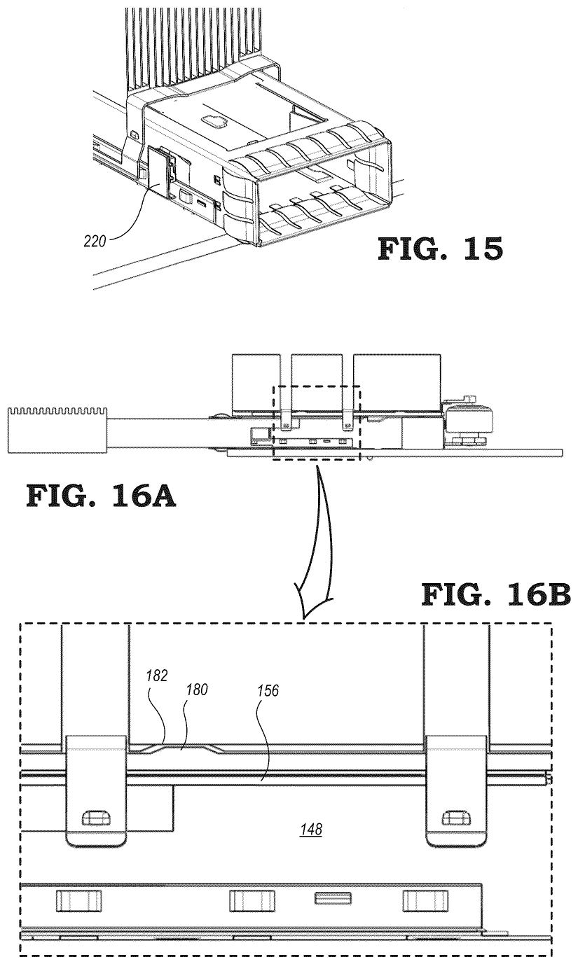

FIG. 15 is a diagram illustrating a perspective view of a mechanical element (e.g., switch 220) on the socket for detecting when the pluggable optical module is plugged in. In this embodiment, the switch 220 may be activated between steps 5 and 6 above. For example, the switch 220 may be positioned just outside the second latch 210 of the socket. The switch 220 may be mounted and assembled with the socket (or cage) itself by performing small modifications outside the cage.

Thus, additional steps for enabling the release of the module, the following procedure may be performed (e.g., between steps 5 and 6) with respect to the location of the second latch 210:
5a. The second latch 210 is pushed outwards by about 0.5 mm,
5b. This movement presses the switch 220,
5c. Switch 220 signal goes to the controller 200,
5d. Controller 200 gives signal to motor 164 to pull the slider 186 to push the heat sink assembly 142 upwards,
5e. A gap between the thermal pad 156 and the surface of the module is created,
5f. Pulling-out process from step 6 will continue again,

The positioning mechanism 144 may be configured to perform these steps in as little as a fraction of a second (i.e., within 100s of milliseconds), which will not significantly affect the experience of the operator while removing the pluggable optical module from the socket. Thus, there is little, if any, chance that the module will significantly scrape against the thermal pad. Rather, the heat sink is pulled up before the pluggable optical module makes any significant movements. The heat sink may then remain in a lifted-up position until any insertion takes place again and the same module or a new one is fully inserted and plugged into the connector in the interior of the socket.

Use Case #3: Host Unit Powers Off when Module is Plugged in

FIG. 16A is a diagram illustrating a side view of the heat management apparatus 140 with the heat sink assembly 142 arranged in the second (lower) position. FIG. 16B is a diagram illustrating a zoomed-in side view of the heat management apparatus 140 in the second position. In this condition, the protrusions 180 are positioned within the corresponding grooves 182 to allow the clip 163 (and corresponding flexible components) to suitable press the thermal pad 156 against the top surface 158 of the pluggable optical module 148.

According to another use case, suppose, for example, that the power to the socket 146 is shut off (either intentionally or unintentionally). In some situations, the power may be shut off to allow the operator to remove (or replace) a pluggable optical module. As such, there is an advantage of using active circuits to control the heat sink up-down movements. For example, with automatic lifting, there would be little, if any, chance that the pluggable optical module will scrape against the thermal pad since the heat sink assembly will be lifted. The automatic lifting procedure may include the following steps:
1. While the system is working and the modules are plugged in, the power may suddenly go down,
2. A “dying gasp” signal can be detected by the controller 200,
3. Controller 200 gives an immediate signal to the motor 164 to lift up the heat sink assembly 142,
4. Motor 164 can make a small movement of the lever 204 and slider 186, as needed, to lift up the heat sink,
5. Motor 164 and controller 200 will have limited power for a short amount of time (e.g., 100s of milliseconds) after the dying gasp is triggered, the power being used to charge one or more Super-Caps (not shown) used for dying gasp functionality.
6. Motor 164 and controller 200 will not need much power, so Super Caps will be able to supply this power to the motor 164 for sufficient lifting action,
7. This process ensures that the heat sink will be in the lifted position during this power off condition.

The positioning mechanism 144 may be configured to maintain the heat sink assembly 142 in the first position as a default when power to the socket is off. Also, as discussed herein, the heat management apparatus 140 may further include one or more super capacitors configured to store at least a predetermined amount of charge, wherein, when power to the socket 146 transitions from on to off, the socket 146 is configured to detect a dying gasp signal and cause the one or more super capacitors to supply the predetermined amount of charge to the positioning mechanism 144 to move the heat sink assembly 142 to the first (upper) position.

The socket 146 may further include a connector in its interior 152 configured for engagement with a plug of the heat-generating element (e.g., pluggable optical module 148). The socket 146 may be configured to set a module-absent (MOD_ABS) bit to high when the plug is not engaged with the connector and set the MOD_ABS bit to low when the plug is engaged with the connector. The positioning mechanism 144 may be configured to move the heat sink assembly 142 to the first (upper) position when the MOD_ABS bit is high and move the heat sink assembly to the second (lower) position when the MOD_ABS bit is low. The socket 146 may further include a mechanical element (e.g., second latch 210) that is triggered when a user starts to remove the pluggable optical module from the socket 146. For example, when the mechanical element is triggered, the socket 146 may be configured to send a signal to the positioning mechanism 144 (e.g., via the controller 200) to instruct the positioning mechanism 144 to move the heat sink assembly 142 to the first position.

### Additional Aspects of the Heat Dissipating Systems

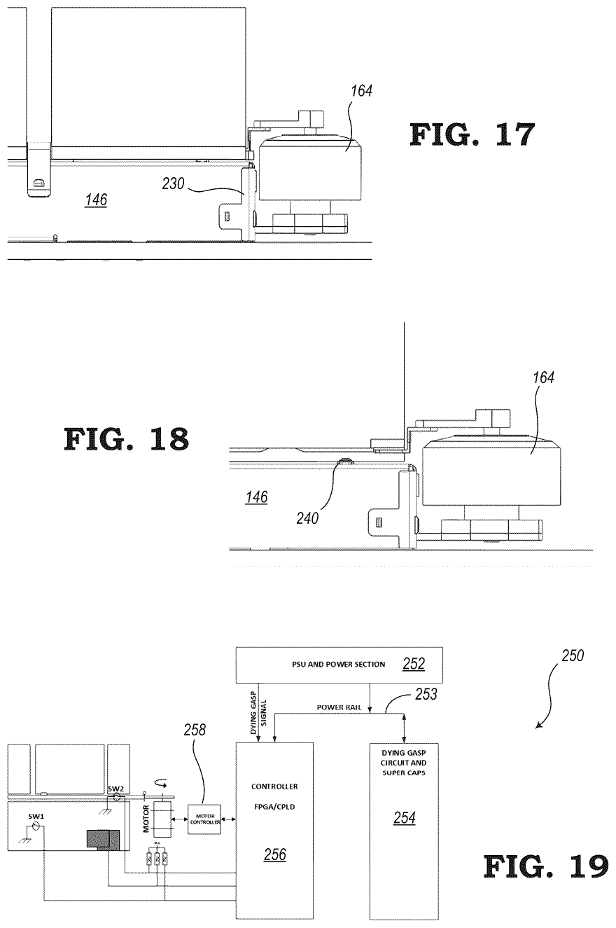

FIG. 17 is a diagram illustrating an arrangement of the motor 164 according to one implementation. Regarding the motor 164 and its assembly, a QSFP-DD cage (or other suitable socket) may include a support structure 230 having flanges to mount the motor 164. The motor 164 may be a stepper motor, which is normally highly reliability. Small form factors of motors are available (e.g., similar to devices used in the camera industry) and may be advantageous in some embodiments to minimum the space needed to perform the movement duties and to allow adequate airflow for cooling down the components.

The socket or cage may be modified to add flanges to hold the motor 164 and may be part of the cage. The motor 164 may be mounted such that space below is more than about 2.5 mm, which may be sufficient room to mount decoupling capacitors or inductors used for QSFP-DD power filtering. Thus, there is very little infringement into the PCB layout near the QSFP-DD connector. Thus, the motor size and mounting location is such that it does not hinder airflow direction and is mounted behind the cage and may be positioned away from other connectors and cables.

FIG. 18 is a diagram illustrating an electro-mechanical switch 240 attached to the socket for detecting the position of the heat sink assembly 142 with respect to the socket. In some respects, the electro-mechanical switch 240 may be used for motor calibration. In operation, the circuit may include:
1. The electro-mechanical switch 240 is placed between heat sink and QSFP-DD cage,
2. The electro-mechanical switch 240 is pressed when the heat sink is lowered down into position,
3. When the heat sink is lifted up, the electro-mechanical switch 240 will be in lifted up (not pressed) position,

The electro-mechanical switch 240 may be used where a) the controller 200 will get feedback if the heat sink is pressed or lifted, b) the controller 200 may automatically calibrate the motor 164 operation to adjust the rotational positions to thereby adjust the slider 186 movement, and c) the controller 200 may perform a self-calibration algorithm to calibrate the angles and extent of motor movements.

FIG. 19 is a schematic diagram illustrating an embodiment of a dying gasp control device 250. In this embodiment, the dying gasp control device 250 may include a Power Supply Unit (PSU) and power section 252, a power rail 253, a dying gasp circuit and super-caps 254, a controller 256, and a motor controller 258.

In operation, a dying gasp signal may come from the PSU and power section 252 as a “good power” signal or can come from the power rail 253 as +12V using a sensor circuit. If this signal comes, the controller 256 is informed that the power is transitioning off and that it is time for the heat sink assembly 142 to be lifted. The controller 256 causes the motor controller 258 to trigger the motor 164 to lift the heat sink. Power can be applied for a certain amount of time to the dying gasp circuit and super-caps 254. The power or charge from the dying gasp circuit and super-caps 254 is configured to be sufficient to move the slider 186 and lift the heat sink. In this way, the motor may receive power from the super-caps.

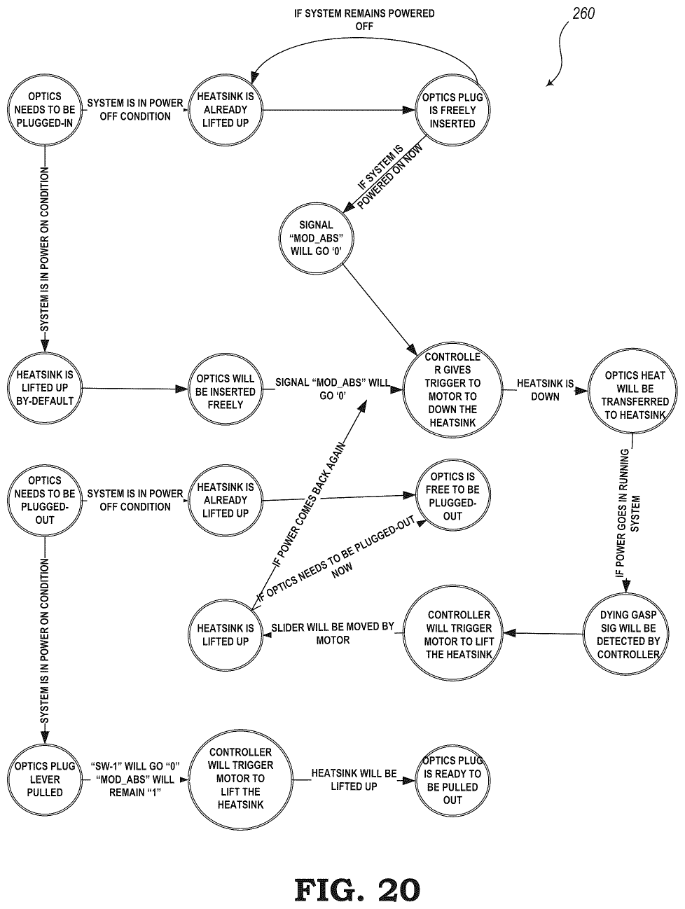

FIG. 20 is an embodiment of a state diagram 260 illustrating actions and states of the heat management apparatus 140. According to one implementation, the state diagram 260 may include the process of self-heating where the heat sink assembly 142 is not used for dissipating heat, but instead the heat inherently generated by the module is allowed to heat up the module when operating in a low temperature environment. For example, this may have the additional benefit of increasing the plug to heat sink thermal resistance for low inlet temperature operation. It can be used to self-heat the commercial optics to a suitable operating temperature above 0° C.

Also, an algorithm may be used so the heat sink assembly 142 may be lifted up when the temperature of the optical module (e.g., pluggable optical module 148) is close to 0° C. By raising the heat sink, the heat flow path will be cut-off allowing optics module to heat up. When the optics is to be cooled in high ambient temps, heat sink will drop on the optics case. It has been found that this is a highly efficient self-cooling method.

The state diagram 260 also includes use for plug or module testing. The method may include lifting so that the module itself (e.g., pluggable optical module 148) is not scratched during plug or module insertion or removal for testing purposes, to thereby preserve the appearance of the module.

### Heat Management Process

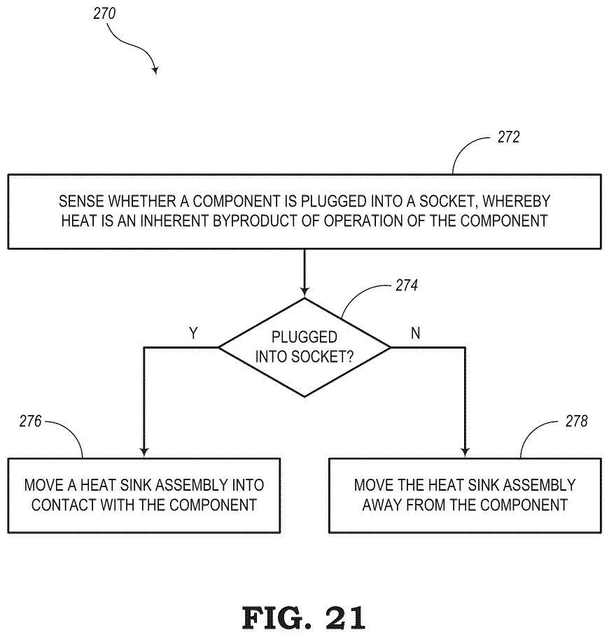

FIG. 21 is a block diagram illustrating an embodiment of a process 270 for managing heat in an electronic, electromechanical, or electro-optical component. A process 270 includes a step of determining whether a component is plugged into a socket, whereby heat is an inherent byproduct of operation of the component, as indicated in block 272. In decision block 274, if it is determined that the component is plugged into the socket, the process proceeds to block 276. Otherwise (if the component is not plugged into the socket), the process proceeds to block 278. In response to sensing that the component is plugged into the socket, block 276 includes the step of moving a heat sink assembly into contact with the component via active circuitry. In response to sensing that the component is not plugged into the socket, block 278 includes the step of moving the heat sink assembly away from the component via the active circuitry.

According to some embodiments, the component may be a pluggable optical module (e.g., QSFP-DD module). Also, each of the steps of moving the heat sink assembly into contact with the component (block 276) and moving the heat sink assembly away from the component (block 278) may include operating a motor to slide one or more reciprocating arms within one or more corresponding channels in the heat sink assembly, wherein each of the one or more reciprocating arms may include one or more protrusions corresponding to one or more grooves in the respective channel.

### Advantages

Therefore, the embodiments of the present disclosure include several advantages over the conventional systems. The embodiments are configured to provide a reduction of 15° C. of the case temperature (T_{c}) for a 25 W QSFP-DD optics module or other similar modules, which can improve the functionality of module and allow it to operate within an acceptable temperature range and not cause damage to the device from overheating. Also, no extra human involvement is required during the plugging in and unplugging processes, but automatic lifting of the heat sink assembly can be performed by the positioning mechanism described herein.

Furthermore, the embodiments can be applied to any type of cooling method for any type of heat sink (e.g., zipper fins, liquid cooling, vapor chamber based heat sinks, etc.), since the lowering of the heat sink can be applied to multiple types of systems, not just optics or electro-optical modules. Also, the cost to implement such a system is relatively low and may simply include the use of a few extra components, such as switches, motors, etc., which are typically not too costly. The controller may be a small FPGA, CPLD, microcontroller device, etc.

Additional advantages may include, for example, for multiple optical ports, common controller device can be used. Also, a prototype of the proposed solution may have a customized QSFP-DD cage in which both switches, motor, slider, thermal pad, harness connector may be integrated. In addition, very little extra real estate is required on the PCB.

Also, not much power is required for operating the motor in the present embodiments, because these types of motors are not power hungry. Also, the use of the motor might seldom come into play, since it is only used when optics modules are plugged in or removed, which may be infrequent. Another advantage of the present systems and methods is that there will be little or no possibility of damage to the thermal pad.

The embodiments described herein may be used to self-heat the optics plugs to operate commercial plugs into extended temperature ranges. The same solution can be implemented for other types of connectors, such as CFP2-DCO, riding heat sink on OSFPs, etc. The heat sink control circuit (e.g., switches, motor, etc.) can take power only when up or down movements of the heat sink is required. No power requirements in free position when heat sink is in lifted position or down position. Also, self-calibration of the motor movements is possible.

Both hot and cold inlet conditions are covered in the embodiments and are described in the present disclosure. In a hot inlet condition, contact resistance is decreased and in cold inlet condition the contact resistance is increased. Other solutions may be used to decrease the plug to heat sink contact resistance, which can be helpful on the hot inlet temperature end. It is believed, however, that no prior solutions exist that are able to resolve both the high and cold inlet temperature challenge.

The embodiment may use active circuitry for heat sink up/down movements, instead of passive heat sink movements or manually operated movements. The mechanisms may involve transverse heat sink movement which reduces the chance of the thermal pad getting damaged. The proposed solution has thermal pads with good thermal conductivity present between heat sink pedestal and optics plugs, instead of solid metal to metal dry contact in present industry. Also, the solutions of the present disclosure use advanced sensing of optics plug-out movement and take timely action of heat sink lift-up movement before the actual optics plug is pulled out. Also, the use of the optics connector signal “MOD_ABS” to control heat sink position is believed to be novel.

The present embodiments can keep the heat sink in the lifted-up position in power off conditions and as a default in powered on conditions. The heat sink may come into contact with the optics plug only when it is needed to transfer the heat. Also, the present disclosure includes inbuilt solutions with self-heating of optics modules without leaking optics power from the heat sink.

Also, the present solutions use the heat sink in a bi-stable condition (i.e., the heat sink is stable in lifted up position as well as in the down position). However, conventional systems only have monostable heat sinks (e.g., stable only in down position). Furthermore, embodiments are capable of doing self-calibration of motor movements using inbuilt algorithms in the controller. Also, the slider attached to the motor and the clip design can be modified according to various embodiments for optimum pressure on the optics modules to get maximum thermal performance.

A further advantage includes the reduction in the thermal resistance between the optical plug and heatsink for high inlet temperatures as well as increasing the thermal resistance between the optical plug and heatsink for low inlet temperatures without the use of additional heaters. That is, the positioning mechanism 144 can provide various different levels of thermal resistance, such as based on overall temperature. For example, in a cold environment, the thermal resistance can be set to allow more heat to remain. Conversely, in a hot environment, the thermal resistance can be set to dissipate more heat. Another advantage is the approach for dropping down the heatsink after plug insertion does not reduce the surface area of the heatsink unlike the other approaches, such as the mechanical lifter approach.

### CONCLUSION

Although the present disclosure has been illustrated and described herein with reference to various embodiments and examples, it will be readily apparent to those of ordinary skill in the art that other embodiments and examples may perform similar functions, achieve like results, and/or provide other advantages. Modifications, additions, or omissions may be made to the systems, apparatuses, and methods described herein without departing from the spirit and scope of the present disclosure. All equivalent or alternative embodiments that fall within the spirit and scope of the present disclosure are contemplated thereby and are intended to be covered by the following claims.

What is claimed is:

1. A heat management apparatus in network equipment for a pluggable optical module, the heat management apparatus comprising:
a socket having an insertion opening configured to allow a pluggable optical module to be at least partially inserted within an interior of the socket;
a heat sink assembly configured to dissipate heat generated by the heat-generating element; and
a positioning mechanism including active circuitry configured to move the heat sink assembly to a first position with respect to the socket while the pluggable optical module is being inserted into or removed from the insertion opening and further configured to move the heat sink assembly to a second position with respect to the socket after the pluggable optical module has been arranged within the interior of the socket.

2. The heat management apparatus of claim 1, wherein the socket further includes a window, wherein the positioning mechanism is configured to move the heat sink assembly out of and/or away from the window to the first position while the pluggable optical module is being inserted into or removed from the insertion opening, and wherein the positioning mechanism is configured to move the heat sink assembly towards and/or into the window to the second position after the pluggable optical module has been arranged within the interior of the socket.

3. The heat management apparatus of claim 1, wherein, in the second position, the heat sink assembly contacts the pluggable optical module.

4. The heat management apparatus of claim 1, wherein the heat sink assembly includes a thermal pad having a Thermal Interface Material (TIM), the thermal pad configured to contact a surface of the pluggable optical module when the positioning mechanism has moved the heat sink assembly to the second position.

5. The heat management apparatus of claim 4, whereby moving the heat sink assembly to the first position while the pluggable optical module is being inserted into or removed from the insertion opening avoids wear and tear on the thermal pad.

6. The heat management apparatus of claim 4, wherein the heat sink assembly further includes a base, one or more groups of fins extending from the base, a pedestal arranged between the base and the thermal pad, a thread fiber net, and a metal strip configured to hold the thread fiber net to the thermal pad.

7. The heat management apparatus of claim 1, wherein the positioning mechanism includes one or more reciprocating arms configured to slide within one or more corresponding channels in the heat sink assembly, and wherein each of the one or more reciprocating arms includes one or more protrusions corresponding to one or more grooves in the respective channel.

8. The heat management apparatus of claim 7, wherein the positioning mechanism further includes a stepper motor configured to move the one or more reciprocating arms in a reciprocating manner within the one or more corresponding channels.

9. The heat management apparatus of claim 1, wherein the positioning mechanism is located adjacent to the heat sink thereby avoiding any surface area of the heat sink.

10. The heat management apparatus of claim 1, wherein the pluggable optical module (148) is Quad Small Form Factor Pluggable (QSFP) or variant thereof.

11. The heat management apparatus of claim 1, wherein the socket is arranged on a circuit board.

12. The heat management apparatus of claim 1, further comprising a clip configured to support the heat sink assembly while allowing the heat sink assembly to move in a substantially linear manner between the first position and the second position.

13. The heat management apparatus of claim 1, wherein the positioning mechanism is configured to maintain the heat sink assembly in the first position as a default when power to the socket is off.

14. The heat management apparatus of claim 13, further comprising one or more super capacitors configured to store at least a predetermined amount of charge, wherein, when power to the socket transitions from on to off, the socket is configured to detect a dying gasp signal and cause the one or more super capacitors to supply the predetermined amount of charge to the positioning mechanism to move the heat sink assembly to the first position.

15. The heat management apparatus of claim 1, wherein the socket further includes a connector configured for engagement with a plug of the heat-generating element, wherein the socket is configured to set a module-absent (MOD_ABS) bit to high when the plug is not engaged with the connector and set the MOD_ABS bit to low when the plug is engaged with the connector, and wherein the positioning mechanism is configured to move the heat sink assembly to the first position when the MOD_ABS bit is high and move the heat sink assembly to the second position when the MOD_ABS bit is low.

16. The heat management apparatus of claim 1, wherein the socket further includes a mechanical element that is triggered when a user starts to remove the pluggable optical module from the socket, and wherein, when the mechanical element is triggered, the socket is configured to send a signal to the positioning mechanism to instruct the positioning mechanism to move the heat sink assembly to the first position.

17. The heat management apparatus of claim 1, wherein the positioning mechanism is configured to move the heat sink assembly to the first position when a low temperature condition is detected.

18. A method for managing heat of a pluggable optical module in network equipment, the method comprising the steps of:
sensing whether the pluggable optical module is plugged into a socket, whereby heat is an inherent byproduct of operation of the pluggable optical module;
in response to sensing that the pluggable optical module is plugged into the socket, moving a heat sink assembly into contact with the pluggable optical module via active circuitry; and
in response to sensing that the pluggable optical module is not plugged into the socket, moving the heat sink assembly away from the pluggable optical module via the active circuitry.

19. The method of claim 18, wherein the heat sink assembly includes a thermal pad having a Thermal Interface Material (TIM), the thermal pad configured to contact a surface of the pluggable optical module when a positioning mechanism has moved the heat sink assembly into contact with the pluggable optical module.

20. The method of claim 18, wherein each of the steps of moving the heat sink assembly into contact with the component and moving the heat sink assembly away from the pluggable optical module includes operating a motor to slide one or more reciprocating arms within one or more corresponding channels in the heat sink assembly, and wherein each of the one or more reciprocating arms includes one or more protrusions corresponding to one or more grooves in the respective channel.
